(19) United States
(12) Patent Application Publication
(10) Pub. No.: US 2008/0042220 A1
(43) Pub. Date: Feb. 21, 2008

(54) GATE ELECTRODE FORMING METHOD FOR SEMICONDUCTOR DEVICE

(76) Inventor: Mun-Sub Hwang, Daejeon (KR)

Correspondence Address: SHERR & NOURSE, PLLC, 620 HERNDON PARKWAY, SUITE 200, HERNDON, VA, 20170, US

(21) Appl. No.: 11/841,027

(22) Filed: Aug. 20, 2007

(30) Foreign Application Priority Data
Aug. 21, 2006 (KR) 10-2006-0078666

(51) Int. Cl. H01L 29/94; H01L 21/336

(52) U.S. Cl. 257/408; 438/301; 257/E29.345; 257/E21.409

(57) ABSTRACT

A method for forming an LDD structure of a gate electrode of a MOSFET. The gate electrode may be formed by sequentially depositing a gate oxide layer and a poly silicon layer over a semiconductor substrate. A photo resist pattern may be formed over the resultant structure. A gate electrode may be formed by an etch using the photo resist pattern as a mask. An LDD area may be formed by ion implanting a low-concentration dopant using the gate electrode as a mask. After depositing a spacer layer over the upper surface of the substrate, a spacer may be formed by etching. A source/drain area may be formed by ion implanting a high-concentration dopant using the gate electrode and the spacer as a mask. A portion of the gate oxide layer where the gate oxide layer and the LLD area overlap may be removed by performing an etch process over the resultant structure.

The present application claims priority under 35 U.S.C. 119 to Korean Patent Application No. 10-2006-0078666, filed on Aug. 21, 2006, which is hereby incorporated by reference in its entirety.

### BACKGROUND

In the related art, to form a lightly doped drain (LDD) structure, a layer of silicon oxide (SiO2) may be used as a spacer. However, in processes where TiSix will be used as silicide material, Ti has reacted with the SiO2, creating a short circuit between a gate and a source/drain. To deal with this issue, a silicon nitride layer, which does not react with the titanium, may be used as the spacer layer material.

When silicon nitride layer is used as the spacer, defects may be generated by stresses at the interfaces between the SiN layer and the substrate in a subsequent annealing process. To deal with this issue, a thin buffer oxide layer may be used therewith.

As shown in the FIG. 1, a MOSFET transistor using a silicon nitride layer as a spacer includes a gate oxide layer 20 and a gate electrode 30 sequentially formed over the upper of a semiconductor substrate 10. A buffer oxide layer 40 may be formed over both side walls of the gate electrode 30 and the surface of the semiconductor substrate. A spacer 50 may be formed over the buffer oxide layer 40. A LDD ion implanting area 60 may be formed by ion implanting a low-concentration dopant using the gate electrode 30 as a mask. A source/drain ion implanting area 70 may be formed by ion implanting a high-concentration dopant using the spacer 50 and the gate electrode 30 as a mask. A silicide layer 80 may be formed over the upper portions of the gate electrode 30 and the source/drain ion implanting area 70.

However, with the semiconductor integrated circuit using the LDD structure according to the related art, leakage current may occur in the region (“A” portion in the FIG. 1) where the gate oxide layer and the LDD ion implanting area overlap. Accordingly, the characteristics of a device may be deteriorated, and the operating speed of the device may be reduced due to a resistance-capacitance (RC) delay.

### SUMMARY

Embodiments relate to a forming method for a semiconductor device, and in particular relate to a gate electrode forming method over an LDD structure of a MOSFET semiconductor device.

Embodiments relate to the solution of issues that may arise in forming a MOSFET gate. Embodiments relate to a method of forming a gate electrode which may improve the operating speed of a semiconductor device by eliminating overlap between a gate oxide layer and a LDD ion implanting area, so that leakage current may be reduced and capacitance may be lowered.

The method of forming the gate electrode according to embodiments includes sequentially depositing a gate oxide layer and a poly silicon layer over a semiconductor substrate. A photo resist pattern may be formed over the substrate, and a gate electrode may be etched using the photo resist pattern as a mask. An LDD area may be formed by ion implanting a low-concentration dopant using the gate electrode as a mask. A spacer layer may be deposited over the upper of the substrate, and a spacer may be formed by etching. A source/drain area may be formed by ion implanting a high-concentration dopant using the gate electrode and the spacer as a mask. A portion of the gate oxide layer may be removed by performing an etch process over the resultant structure.

The spacer layer may be formed by one or more of a silicon oxide layer, a buffer oxide layer/silicon nitride layer and a buffer oxide layer/silicon nitride layer/silicon oxide layer. The etch for forming the spacer may be performed by means of an etch-back etch process. The gate oxide layer may be etched using a buffered oxide etchant. The buffered oxide etchant may include a solution in deionized water of NH₄F, HF, and surfactant.

The length of the gate oxide layer which may be removed correspond to a length 20 to 30% of the overall of the gate electrode. The gate oxide layer may be removed by means of a wet etch process wherein an isotropic etch and an anisotropic etch are simultaneously performed.

The resulting MOSFET includes a semiconductor substrate. A gate oxide layer may be formed over said semiconductor substrate. A gate electrode may be formed over said gate oxide layer. A lightly doped drain area having a relatively low concentration dopant may be formed in the substrate. A source/drain area having a relatively high concentration dopant may be formed in the substrate. An air gap is formed between said lightly doped drain area and said gate electrode.

### DRAWINGS

FIG. 1 is a cross-sectional view showing a structure of a MOSFET transistor using a silicon nitride layer as a spacer according to the related art.

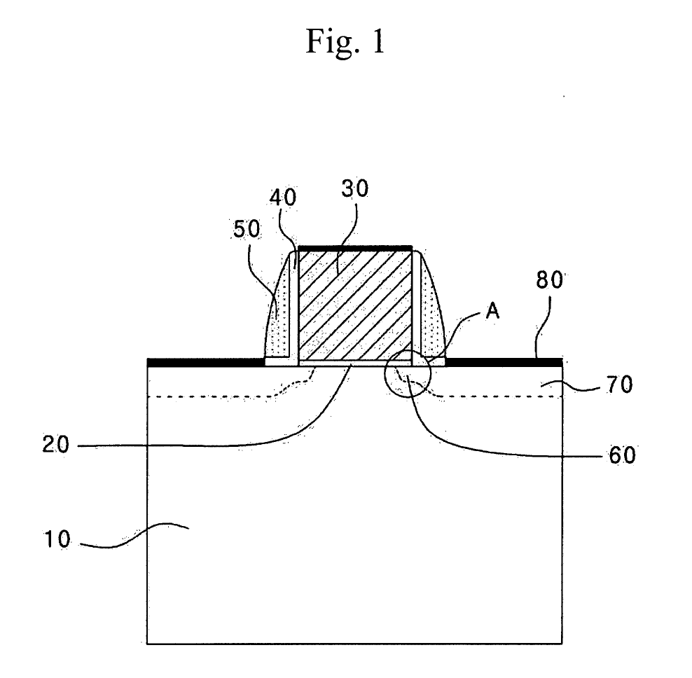

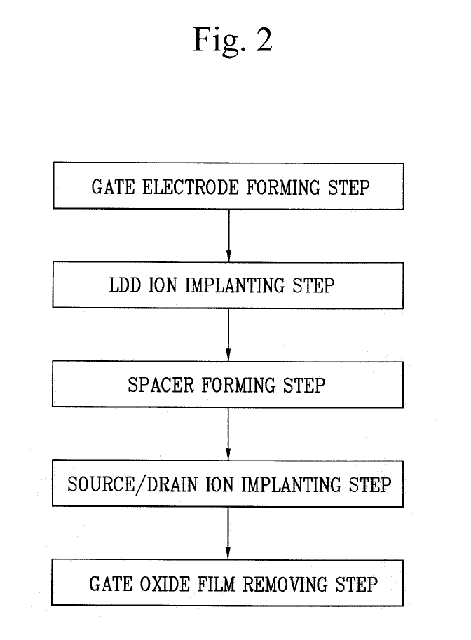

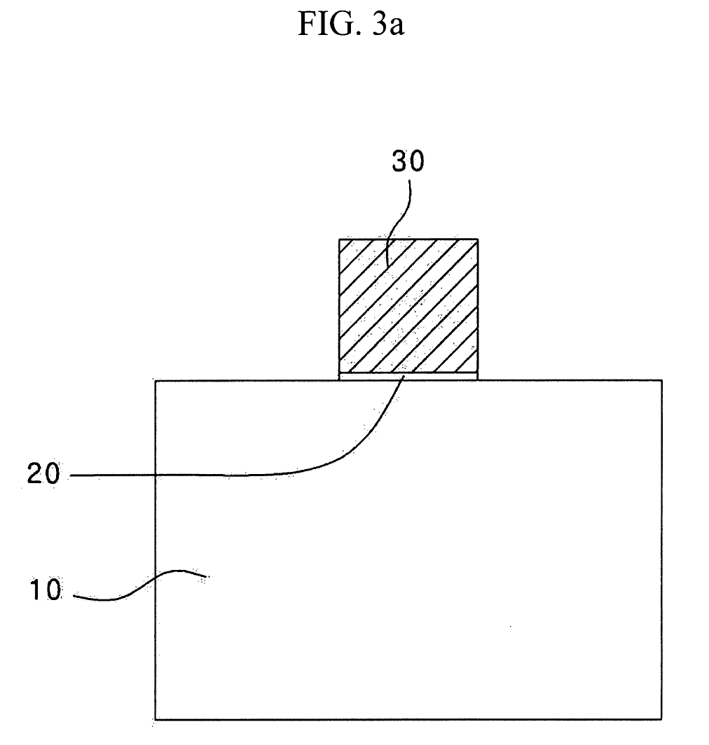

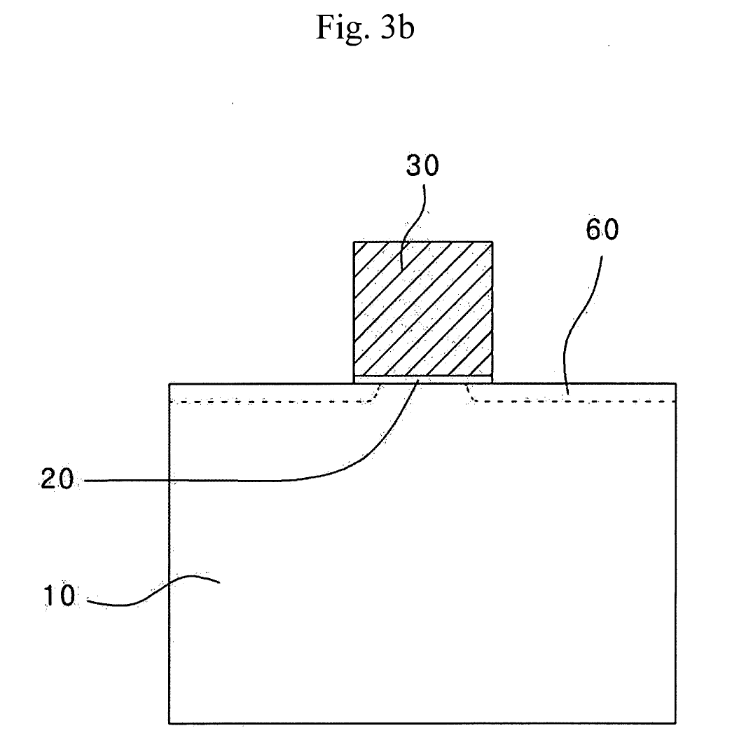

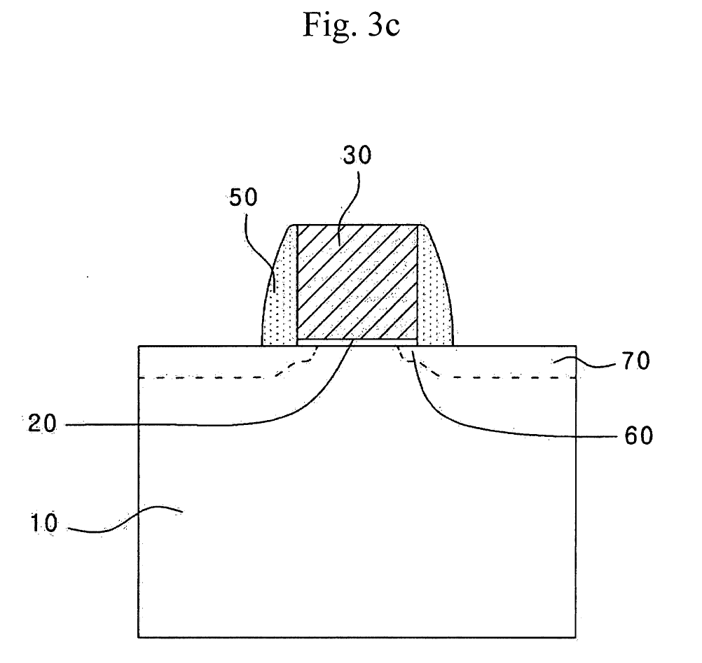

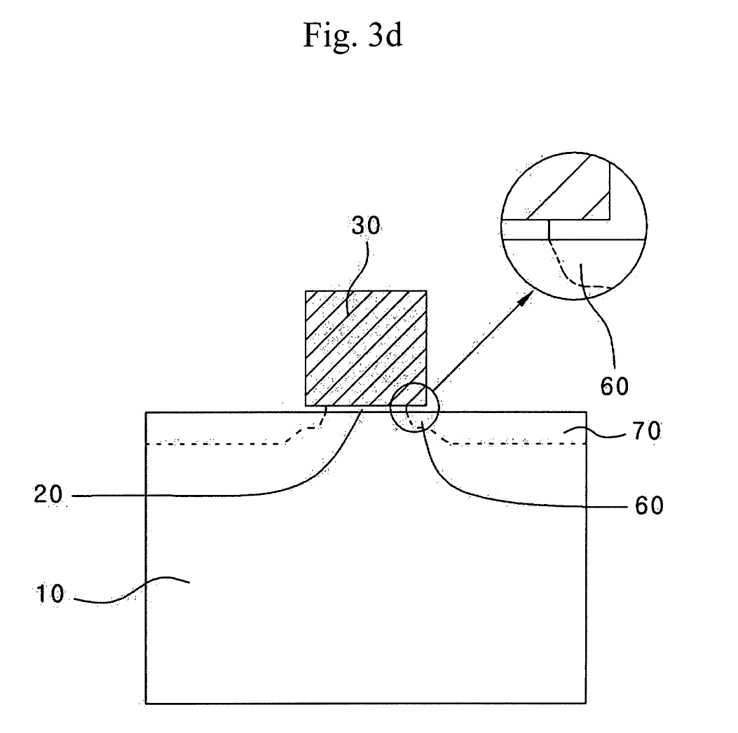

Example FIG. 2 is a process flow-chart showing a method of forming a gate electrode for a semiconductor device according to embodiments.

Example FIGS. 3a to 3d are cross-sectional views of a MOSFET transistor for explaining the method of forming a gate electrode for the semiconductor device according to embodiments.

### DESCRIPTION

As shown in example FIG. 2, a method for forming a gate electrode for a semiconductor device according to embodiments includes a gate electrode forming step, an LDD ion implanting step, a spacer forming step, a source/drain ion implanting step, and a gate oxide layer removing step.

Referring to example FIG. 3, a gate electrode forming step may include sequentially forming a gate oxide layer 20 and a poly silicon layer over a semiconductor substrate 10 in which an active area and a device isolating area are defined. Photolithographic processes may be performed to pattern a gate electrode 30 from the poly silicon layer.

Referring to example FIG. 3b, in the LDD ion implanting step, an ion implantation process may be used to implant a low-concentration dopant into the semiconductor substrate 10 using the gate electrode 30 as a mask.

Referring to example FIG. 3c, in the spacer forming step, after depositing a spacer layer over the semiconductor substrate 10 including the gate electrode 30, an etch-back etching process may be used to form a spacer 50. The spacer layer may be formed of a silicon oxide layer in a chemical vapor deposition (CVD) method. The spacer layer may also be formed in a stacked structure of a buffer oxide layer/silicon nitride layer, or it may be formed of a stacked buffer oxide layer/silicon nitride layer/silicon oxide layer. In the source/drain ion implanting step, a high concentration dopant may be implanted into the semiconductor substrate 10 by ion implantation using the gate electrode 30 and the spacer 50 as a mask to form a source/drain area.

Referring to example FIG. 3d, in the gate oxide layer removing step, an isotropic wet etch process may remove a portion of the gate oxide layer 20. The portion of the gate oxide layer 20 removed by the wet etch process is an edge portion, hereinafter referred to as an overlap area, of the gate oxide layer where the gate electrode and LDD area formed in the LLD ion implanting step overlap.

Accordingly, the gate oxide layer in the overlap area is replaced with low-k air, which may help to prevent leakage current between the gate electrode and the source/drain area. In addition, the capacitance of the overlap area is lowered, which may improve the operating speed of the semiconductor device, by reducing a resistance-capacitance delay. It may also be possible to implement a shorter gate length by the gate oxide removing step.

In the gate oxide removing step, a buffered oxide etchant may be used. For example, a solution in deionized water of about 30% NH₄F, about 6% HF, and surfactant at about 400 ppm may be used. The length of the gate oxide layer etched may correspond to 20 to 30% of the overall length of the gate electrode.

As described in detail, with the method of forming a gate electrode according to embodiments, the step of removing the gate oxide layer where the gate oxide layer and the LDD area overlap using the wet etch process may reduce leakage current and stray capacitance. This may improve the operating speed of the device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
depositing a gate oxide layer over a semiconductor substrate;
depositing a poly silicon layer over a semiconductor substrate;
forming a gate electrode by etching;
forming a LDD area by ion implantation of a relatively low concentration dopant using the gate electrode as a mask;
depositing a spacer layer over the upper surface of the substrate;
forming a spacer by etching;
forming a source/drain area by ion implantation of a relatively high concentration dopant using the gate electrode and the spacer as a mask; and
removing a portion of the gate oxide layer by etching.

2. The method of claim 1, wherein the spacer layer is formed of a silicon oxide layer.

3. The method of claim 1, wherein the spacer layer is formed of a stacked buffer oxide layer and silicon nitride layer.

4. The method of claim 1, wherein the spacer layer is formed of a buffer oxide layer, a silicon nitride layer and a silicon oxide layer.

5. The method of claim 1, wherein said forming a spacer by etching comprises an etch-back etching process.

6. The method of claim 1, wherein said gate oxide layer is etched using a buffered oxide etchant.

7. The method of claim 6, wherein the buffered oxide etchant comprises solution in deionized water including NH₄F, HF, and surfactant.

8. The method of claim 1, wherein the gate oxide layer removed corresponds to a length of 20 to 30 percent of the overall of the gate electrode.

9. The method of claim 1, wherein said removing a portion of the gate oxide layer by etching comprises a wet etch process.

10. The method of claim 9, wherein said wet etch process comprises an isotropic etch and an anisotropic etch which are simultaneously performed.

11. The method of claim 1, wherein said forming a gate electrode by etching comprises forming a photo resist pattern.

12. The method of claim 11, wherein said forming a gate electrode by etching comprises using said photo resist pattern as a mask.

13. The method of claim 1, wherein said method comprises forming a metal oxide semiconductor field effect transistor.

14. The method of claim 1, wherein said spacer layer is formed by a chemical vapor deposition method.

15. An apparatus comprising:
a semiconductor substrate;
a gate oxide layer formed over said semiconductor substrate;
a gate electrode formed over said gate oxide layer;
a lightly doped drain area having a relatively low concentration dopant formed in said substrate;
a source/drain area having a relatively high concentration dopant formed in said substrate; and
an air gap between said lightly doped drain area and said gate electrode.

16. The apparatus of claim 15, wherein the gate electrode comprises poly silicon.

17. The apparatus of claim 15, wherein said air gap extends between said gate electrode and said lightly doped drain region a distance corresponding to between 20% and 30% of the overall length of the gate electrode.

18. The apparatus of claim 15, wherein said apparatus comprises a metal oxide semiconductor field effect transistor.
